(19) United States
(12) Patent Application Publication
(10) Pub. No.: US 2009/0044972 A1
(43) Pub. Date: Feb. 19, 2009

(54) Circuit board, method of forming wiring pattern, and method of manufacturing circuit board

(75) Inventors: Masayuki Kitajima, Kawasaki (JP); Takeshi Ishitsuka, Kawasaki (JP); Satoshi Emoto, Kawasaki (JP); Yutaka Noda, Kawasaki (JP); Seiichi Shimoura, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED of Kawasaki, Japan

(21) Appl. No.: 12/155,261

(22) Filed: May 30, 2008

(30) Foreign Application Priority Data
Aug. 17, 2007 (JP) 2007-212972

(51) Int. Cl. H05K 3/12; H05K 1/09

(52) U.S. Cl. 174/257; 427/98.4

(57) ABSTRACT

When manufacturing a circuit board, a wiring pattern is printed on a substrate with a conductive paste formed of metal powder and thermoplastic resin, and then the conductive paste is subjected to a heating treatment and a pressing treatment.

### BACKGROUND OF THE INVENTION

1. Field of the Invention

The present invention relates to a circuit board on which wiring patterns are printed by using a conductive silver paste formed of metal powder and resin, a method of forming the wiring patterns, and a method of manufacturing the circuit board.

2. Description of the Related Art

A conductive paste is typically applied on a substrate when printing wiring patterns on the substrate. A conductive paste is generally formed of metal powder and resin, which functions as an adhesive. Silver power has been widely used as metal powder in such conductive pastes.

More specifically, conductive pastes that contain about 60 weight percent of silver powder of particle size of about 8 micrometers to 15 micrometers and that have the resistivity ratio of about 20 μO·cm to 40 μO·cm are widely used. On the other hand, a carbon paste has a resistivity ratio of about 30,000 μO·cm to 100,000 μO·cm. Such conductive paste is used for various purposes such as a wiring pattern material for a polyethylene terephthalate (PET) membrane substrate such as packaging for low heat resistant electronic components, keyboards, and touch panels, which can be used even if electric resistance thereof is high.

Silver, however, undergoes migration in the presence of moisture. Japanese Patent Application Laid-open No. 2005-109311, for example, discloses a technique for reducing the silver migration. Specifically, Japanese Patent Application Laid-open No. 2005-109311 discloses a circuit board in which carbon paste formed mainly of carbon is coated on a surface of wiring patterns that is printed on a substrate by using a conductive paste formed of a mixture of silver powder and adhesive resin.

On the other hand, Japanese Patent Application Laid-open No. H7-45159 discloses a wiring circuit board that is smooth. Specifically, the wiring circuit board is made smooth by performing a pressing and heating treatment for wiring patterns printed on a substrate when the wiring circuit board that has the wiring patterns printed on the substrate by using a conductive paste formed of a mixture of metal powder and adhesive resin is used as a switch substrate of a slide switch. In a smoothed wiring circuit, friction at a junction of the slide switch is reduced and the occurrence of noise at the junction can be reduced.

The conventional technology represented by a technology disclosed in Japanese Patent Application Laid-open No. 2005-109311 has following problems. Silver has a high melting point and is not easily dissolved. Thus, electric conductivity thereof is secured with silver particles point-contacting with each other, with the result that silver has a high electric resistance. Similarly, a carbon paste, which is used to suppress silver migration or separation of wiring patterns from a substrate, has a high wiring resistance. For example, if a carbon paste is applied on a surface of a connector insertion member for the protection thereof, the electric resistance of the connector insertion member increases. Thus, a conductive paste formed of silver powder and resin is not suitable for a wiring pattern of products, such as a micro wiring pattern and a high-speed signal wiring pattern, that require a small electric resistance.

Even the conventional technology represented by a technology disclosed in Japanese Patent Application Laid-open No. H7-45159 is not suitable for wiring patterns of products that require small electric resistance, if the metal powder is formed of metal, such as silver, that has a high melting point and a high electric resistance.

### SUMMARY OF THE INVENTION

It is an object of the present invention to at least partially solve the problems in the conventional technology.

According to an aspect of the present invention, there is provided a circuit board comprising a wiring pattern formed by printing on a substrate and including a conductive paste formed of metal powder and thermoplastic resin, wherein the conductive paste is then subjected to a heating treatment and a pressing treatment.

According to another aspect of the present invention, there is provided a circuit board comprising a wiring pattern formed by printing on a substrate and including a first conductive paste and a second conductive paste printed on the first conductive paste, wherein the first conductive paste is metal powder and thermoplastic resin, the second conductive paste is formed of carbon powder and thermoplastic resin, and the first and the second conductive pastes are then subjected to a heating treatment and a pressing treatment.

According to still another aspect of the present invention, there is provided a method of forming a wiring pattern including printing a wiring pattern on a substrate with a conductive paste formed of metal powder and thermoplastic resin; and subjecting the conductive paste to a heating treatment and a pressing treatment.

According to still another aspect of the present invention, there is provided a method of forming a wiring pattern including printing a wiring pattern on a substrate with a first conductive paste formed of metal powder and thermoplastic resin; printing a second conductive paste formed of carbon powder and thermoplastic resin on the first conductive paste; and subjecting the first and the second conductive pastes to a heating treatment and a pressing treatment.

According to still another aspect of the present invention, there is provided a method of manufacturing a circuit board including printing a wiring pattern on a substrate with a conductive paste formed of metal powder and thermoplastic resin; and subjecting the conductive paste to a heating treatment and a pressing treatment.

According to still another aspect of the present invention, there is provided a method of manufacturing a circuit board including printing a wiring pattern on a substrate with a first conductive paste formed of metal powder and thermoplastic resin; printing a second conductive paste formed of carbon powder and thermoplastic resin on the first conductive paste; and subjecting the first and the second conductive pastes to a heating treatment and a pressing treatment.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1A is a sectional view of a circuit board according to an embodiment of the present invention before heating and pressing;

FIG. 1B is a sectional view of the circuit board shown in FIG. 1A after heating and pressing;

FIG. 2A is a sectional view of a circuit board according to another embodiment of the present invention before heating and pressing;

FIG. 2B is a sectional view of the circuit board shown in FIG. 2A after heating and pressing;

FIG. 3 is a diagram of an application example of the circuit boards shown in FIGS. 1A and 1B;

FIG. 4 is a schematic of a roll press according to still another embodiment of the present invention;

FIG. 5 is a flowchart of manufacturing procedures for a circuit board according to an embodiment of the present invention;

FIG. 6 is a diagram of a roll press heating temperature profile;

FIG. 7 is a diagram of a vacuum press heating temperature profile;

FIG. 8 is a table of evaluation results of conductivities of the circuit board shown in FIG. 1B; and

FIG. 9 is a diagram of film thickness of carbon-containing a conductive paste and resistance of the circuit board shown in FIG. 2B.

### DETAILED DESCRIPTION OF THE PREFERRED EMBODIMENTS

Exemplary embodiments of a circuit board, a method of forming a wiring pattern, and a method of manufacturing the circuit board according to the present invention will be described in detail below, referring to the accompanying drawings. In the embodiments explained below, metal powder and thermoplastic resin that form a conductive paste are silver powder and polyester, respectively. The metal powder is, however, not limited to silver powder, and can be cobalt powder or a mixture of silver and cobalt powders. In addition, the present invention will work with any metal powder that has a high melting point and a high electric resistance.

In the exemplary embodiment below, the following specific materials are used: “LS-415C-CK” (made of silver filler and polyester) manufactured by Asahi Chemical Research Laboratory Co., Ltd. as a conductive paste; “FC-435” (made of carbon filler and polyester) manufactured by Fujikura Kasei Co., Ltd. as a carbon paste; and “Lumirror” (made of polyethylene terephthalate) manufactured by Toray Industries Inc. as a substrate film. Any one of the substrate, the conductive paste, and the carbon paste is flexible, thus the circuit board in the embodiment below is also flexible.

Conductive pastes that contain about 60 weight percent of silver powder of particle size of about 5 micrometers to 30 micrometers are widely used. The resistivity ratio thereof, however, is high, i.e., 20 μO·cm to 40 μO·cm. Therefore, such a conductive paste is widely used as a wiring material for electric devices that can withstand even a high electric resistance.

Because of the resistivity ratio thereof, a conductive paste cannot be used, however, for a micro wiring pattern or for a high-speed signal wiring pattern. Copper that has a resistivity ratio of 1.67 μO·cm, or solder that has a resistivity ratio of 10 μO·cm are more suitable for a micro wiring pattern or for a high-speed signal wiring pattern than such a conductive paste.

If more silver powder is added to the conductive paste to improve resistivity ratio thereof, paste performance thereof drops. This can create problems in a coating process by using a dispenser or silk screen printing.

In recent years, a technology is available by which particle size of silver can be reduced into the order of nanometers and a metal-to-metal bond between silver particles is formed so that resistivity ratio thereof is reduced. A coating formed with such silver, however, is hard and it is not suitable for a flexible substrate, and does not satisfy resistivity requirements for high-speed signal wiring patterns.

Thus, there is a need for a better conductive paste.

A vacuum press or a roll press is used to heat and press a conductive paste. A vacuum press, however, is a batch process, and thus has poor mass productivity. On the other hand, in a roll press, a phenomenon occurs, wherein the roll is seized up by the conductive paste in the heating and pressing. To take care of those issues, in an embodiment of the present invention, the quality of a surface of a roller that is used for the heating and pressing is improved. Because of the improvement in the quality of the roller surface, seizing up of the roll can be prevented, and excellent heating and pressing press can be performed at high speed.

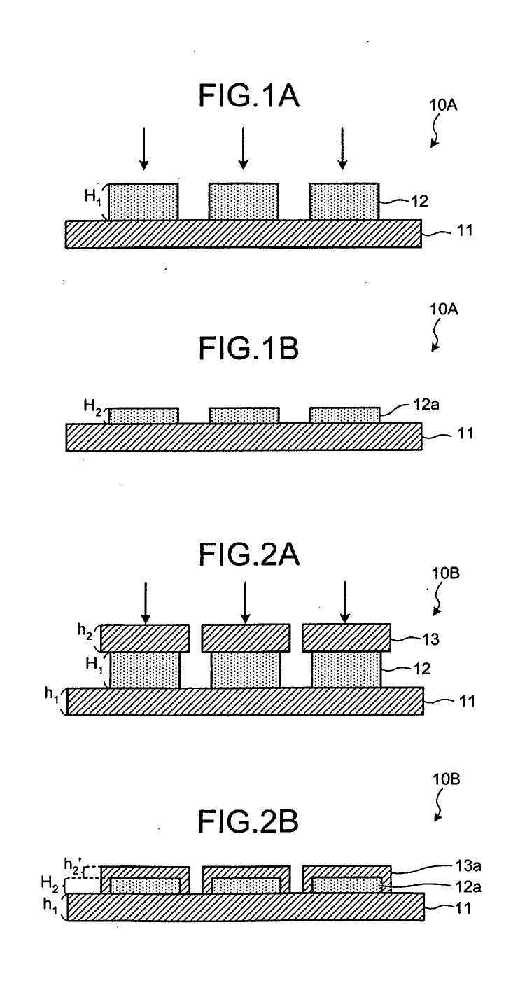

First, a circuit board will be described that is a structure on which a conductive paste into which metal powder and thermoplastic resin are mixed is printed on a substrate, and that is heated and pressed. FIG. 1A is a sectional view of a circuit board 10A after a conductive paste into which metal powder and thermoplastic resin are mixed is printed thereon.

As shown in FIG. 1A, in the circuit board 10A, wiring patterns 12 are printed on a substrate 11 to a height of H₁ by using a conductive paste into which metal powder and thermoplastic resin are mixed.

Printing of the wiring patterns 12 on the substrate 11 is performed by screen printing with a 250-mesh-per-inch printing screen plate using a high solvent-resistant emulsion. The printing patterns have a pattern length of 10 centimeters and a pattern width of 300 micrometers.

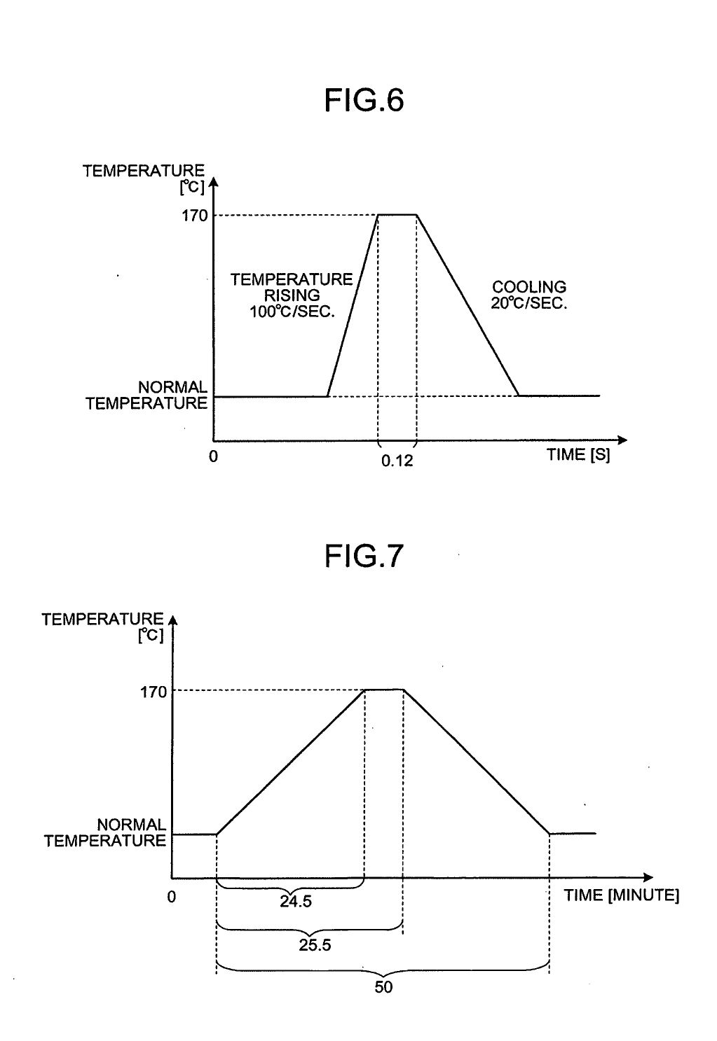

The circuit board 10A is heated and pressed from above, i.e., from the direction of the arrows shown in FIG. 1A. The heating conditions employed in the heating are shown in the roll press heating temperature profile in FIG. 6. First, the circuit board 10A is heated such that the heating temperature rises instantly from the room temperature to 170 degrees centigrade. The circuit board 10A is heated at 170 degrees centigrade for 0.12 second, and then the circuit board 10A is cooled so that the heating temperature falls linearly from 170 degrees centigrade to the room temperature. The circuit board 10A is pressed at a line pressure of 100 kilograms per 50 centimeters simultaneously with the heating with a roll press. While the circuit board 10A is heated and pressed, a roll press conveys the circuit board 10A at a speed of, for example, 1 meter per minute.

The heating temperature may be about 170 degrees centigrade and more to 200 degrees centigrade and less. The circuit board 10A may be pressed at a line pressure of 130 kilograms per 50 centimeters, instead of controlling the heating temperature so that the heating temperature is about 130 degrees centigrade.

The surface of the roll press is mirror finished by using hard chrome. Thus, troubles can be avoided such as seizing up of the roll surface by the conductive paste and the conductive paste sticking to the press roll in the heating and pressing. Therefore, the heating and pressing treatment can be performed speedily, and the circuit board yield and productivity thereof can be improved. The surface of the roll press may be coated by a heat-resistant resin.

The device used for pressing the circuit board 10A is not limited to a roll press. A vacuum press can be used instead of a roll press. Moreover, the circuit board 10A can be pressed from horizontal or vertical direction.

When the pressing is performed by a vacuum press, heating conditions shown in the heating temperature profile in FIG. 7 are can be used. First, the circuit board 10A is heated for 24.5 minutes such that a heating temperature rises linearly from the room temperature to 170 degrees centigrade. Then, the circuit board 10A is further heated such that the heating temperature is maintained at 170 degrees centigrade for 1 minute. Next, the circuit board 10A is cooled for 24.5 minutes such that the heating temperature falls linearly from 170 degrees centigrade to the normal temperature. The circuit board 10A is pressed under a pressure of about 10 megapascals simultaneously with the heating.

When the heating and the pressing are completed, as shown in FIG. 1B, the height of the wiring patterns 12 is reduced to H₂, where H₂<H₁.

Because of such heating and pressing, the density of metal powder particles dispersed in the conductive paste of the wiring patterns 12 is improved, and thus the resistivity ratio of the conductive paste of the wiring patterns 12 is reduced and conductivity efficiency thereof is improved.

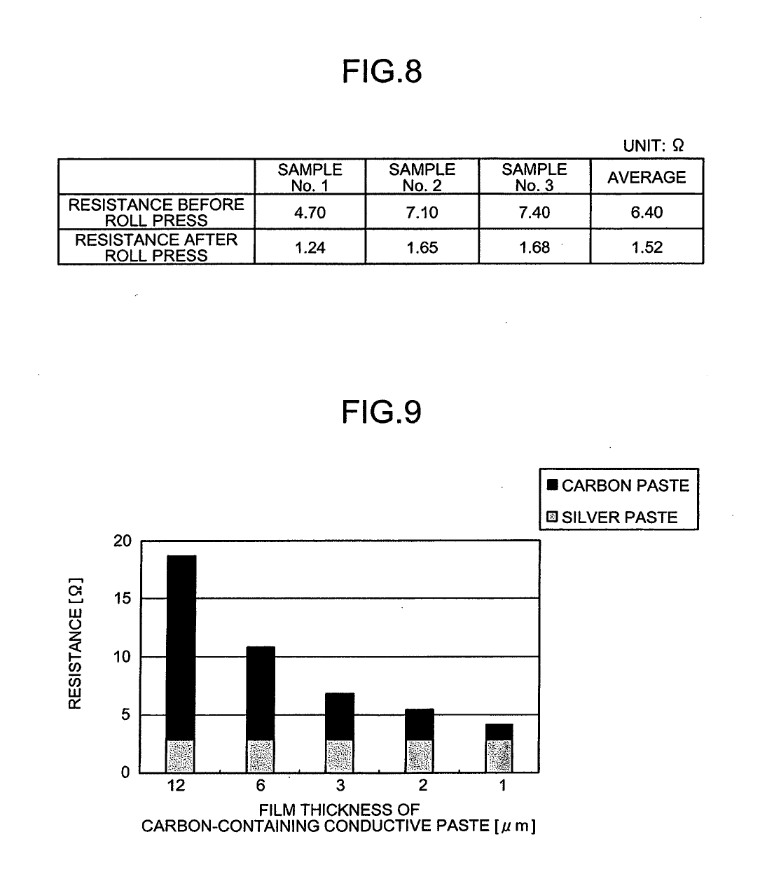

How much improvement in the conductivity efficiency is achieved is explained below referring to FIG. 8. FIG. 8 is a table of evaluation results of conductivities of three sample of a circuit board 10A. In this evaluation, conductivity resistance is measured by applying a probe of a tester (HIOKI 3540 mO Hi TESTER by Hioki E.E. Corporation) to an electric resistance measuring terminal of the circuit board 10A.

As shown in FIG. 8, in all the three samples, the resistances after the roll pressing are smaller than the resistances before the roll pressing. More specifically, the resistances before the roll pressing are 4.70 Ohms, 7.1 Ohms, and 7.40 Ohms for the samples No. 1, No. 2, and No. 3, respectively (the average of these values is 6.40 ohms), and the resistances after the roll pressing are 1.24 ohms, 1.65 ohms, and 1.68 ohms for the samples No. 1, No. 2, and No. 3, respectively (the average of these values is 1.52 ohms). In any one of the samples, the conductivity resistance is smaller after the roll pressing, and thus significant improvement in the conductivity efficiency is affirmed. The circuit board 10A having such a conductivity efficiency can be used for a micro pattern circuit or for a high-speed signal transmission cable.

Next, a wiring circuit board according to another embodiment will be described. In this wiring circuit board, a conductive paste into which metal powder and thermoplastic resin are mixed is printed on the substrate, then a conductive paste into which carbon powder is added is printed thereon, and both of the conductive pastes are heated and pressed. FIG. 2A is a sectional view of a circuit board 10B, wherein the conductive paste into which metal powder and thermoplastic resin are mixed is printed on the substrate and then the conductive paste into which carbon powder is mixed in printed thereon.

As shown in FIG. 2A, in the circuit board 10B, the wiring patterns 12 are printed on the substrate 11 by using a conductive paste into which metal powder and thermoplastic resin are mixed so that the wiring patterns 12 have a height of H₁. This printing condition is the same as the condition shown in FIG. 1A.

As shown in FIG. 2A, in the circuit board 10B, the wiring patterns 12 are printed on the substrate 11 having a film thickness of h₁ by using a conductive paste into which metal powder and thermoplastic resin are mixed so that the wiring patterns 12 have a height of H₁ (several micrometers to several ten micrometers).

A carbon-containing conductive paste 13 into which carbon powder is mixed, having a film thickness of h₂ (several micrometers to several ten micrometers) is printed on each of the printed wiring patterns 12 printed on the substrate so that the entire body of each of the wiring patterns 12 is sandwiched between the substrate 11 and the carbon-containing conductive paste 13, where h₂<H₁.

The circuit board 10B is then heated and pressed from the direction of the arrows shown in FIG. 2A under the same heating and pressing conditions described in FIG. 1A. When the heating and the pressing are completed, as shown in FIG. 2B, the wiring patterns 12 are compressed into wiring patterns 12a having a height of H₂, where H₂<H₁, and the carbon-containing conductive paste 13 is compressed into carbon-containing conductive paste 13a having a film thickness of h₂′, where h₂′<h₂ and h₂′<H₂. In addition, the carbon-containing conductive paste 13a completely encloses the wiring patterns 12a.

By thus heating and pressing the wiring patterns 12 and the carbon-containing conductive paste 13, the density of the metal powder particles dispersed in the conductive paste of the wiring patterns 12 is improved, and thus the resistivity ratio of the conductive paste of the wiring patterns 12 is reduced and the conductivity efficiency thereof is improved. Further, because the carbon-containing conductive paste 13a encloses the wiring patterns 12a, migration of the metal powder in the conductive paste of the wiring patterns 12 is prevented, as well as the wiring patterns 12a are protected. Because the wiring patterns 12a are protected, even if the wiring patterns 12a are micro patterns, separation of the wiring patterns 12a when the circuit board 10B is bent can be prevented. Furthermore, the resistance of the circuit board 10B to bending or breaking and the strength of the circuit board 10B are improved.

How much improvement in the conductivity efficiency is achieved is explained below referring to FIG. 9. FIG. 9 is a diagram of the film thickness of the carbon-containing conductive paste and the resistance of the circuit board 10B.

As shown in FIG. 9, the smaller the film thickness of the carbon-containing conductive paste 13 is with comparison to the film thickness of the wiring patterns 12, the smaller the resistance of the whole circuit board 10B will be. More specifically, for a film thickness of the wiring patterns 12 printed by using the conductive paste into which silver powder and thermoplastic resin are mixed and provides a resistance of about 3 ohms: when the carbon-containing conductive paste 13 has a film thickness of 12 micrometers, then the whole circuit board 10B has a resistance of about 19 ohms; when the carbon-containing conductive paste 13 has a film thickness of 6 micrometers, then the whole circuit board 10B has a resistance of about 11 ohms; when the carbon-containing conductive paste 13 has a film thickness of 3 micrometers, then the whole circuit board 10B has a resistance of about 7 ohms; when the carbon-containing conductive paste 13 has a film thickness of 2 micrometers, then the whole circuit board 10B has a resistance of about 6 ohms; and when the carbon-containing conductive paste 13 has a film thickness of 1 micrometer, then the whole circuit board 10B has a resistance of about 4 ohms.

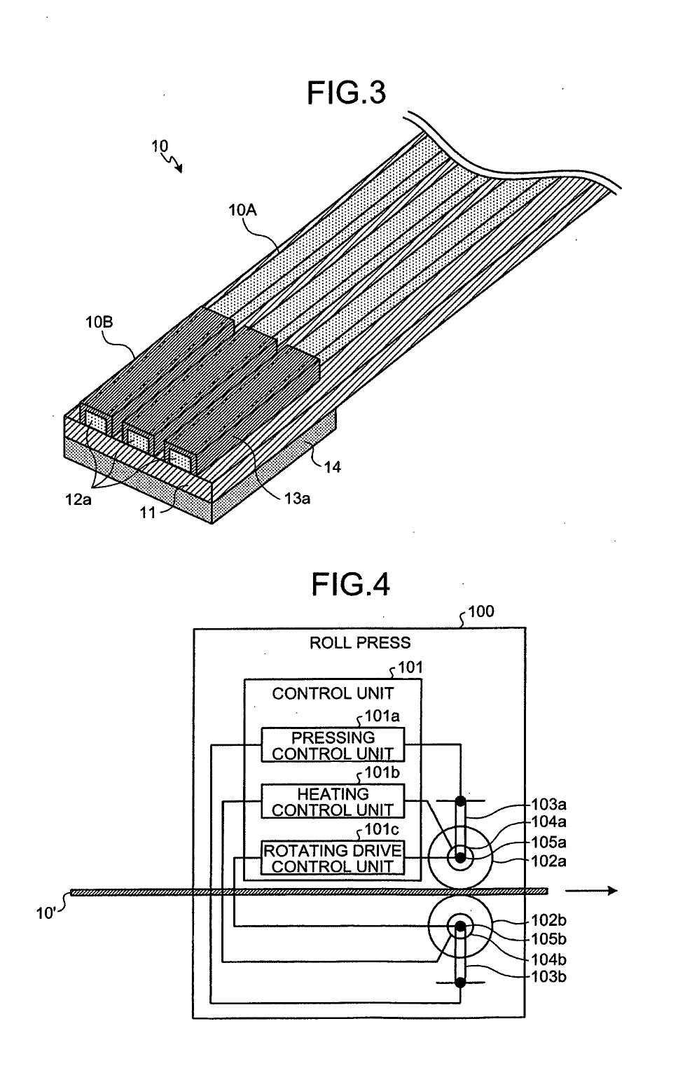

An application example of the circuit boards 10A and 10B is shown in FIG. 3. When a circuit board 10 is manufactured such that an edge thereof has the same configuration as the circuit board 10B and the other portion has the same configuration as the circuit board 10A, the edge is reinforced by the circuit board 10B. Thus, the edge is easily inserted into a connector. As shown in FIG. 3, in the circuit board 10B, a reinforcing board 14 is applied on the side opposite to the surface on which the wiring patterns 12a are printed.

Also in the circuit board 10B, the conductivity efficiency is significantly improved, similarly to the circuit board 10A. Thus, the circuit board 10 is applicable to a micro pattern circuit or to a high-speed signal transmission cable. For example, the circuit board 10 can be used for a cable that connects a main board of a computer device with a peripheral device thereof by a Universal Serial Bus (USB) standard data transfer interface. More specifically, the circuit board 10 is preferable for USB 2.0 high-speed data transfer.

Next, a schematic configuration of the roll press will be described. FIG. 4 is a schematic of a roll press 100 according to still another embodiment of the present invention. As shown in FIG. 4, the roll press 100 conveys a substrate sheet 10′ that is yet to be stripped as the circuit board 10 forward in the direction indicated by the arrow in FIG. 4 while nipping the substrate sheet 10′ between rolls 102a and 102b that are located above and below the substrate sheet 10′ and heating and pressing the substrate sheet 10′.

The surfaces of the rolls 102a and 102b are provided with mirror finishing by using hard chrome or with heat-resistance resin coating. The rolls 102a and 102b are adjustably pressed respectively by pressure cylinders 103a and 103b from above and below. In the rolls 102a and 102b, heating elements 104a and 104b are respectively mounted. These heating elements heat the surfaces of the rolls 102a and 102b.

The rotation driving of rotating drive shafts 105a and 105b rotate the rolls 102a and 102b respectively. Thus, the rolls 102a and 102b move the substrate sheet 10′ forward in the direction of the arrow shown in FIG. 4.

A control unit 101 of the roll press 100 includes a pressing control unit 101a, a heating control unit 101b, and a rotating drive control unit 101c. The pressing control unit 101a controls the pressure cylinders 103a and 103b such that the pressure cylinders maintain a line pressure, for example, of 100 kilograms per 50 centimeters. The heating control unit 101b controls the heating elements 104a and 104b such that the heating elements 104a and 104b heat the substrate sheet 10′ according to the roll press heating temperature profile shown in FIG. 7, for example.

The rotating drive control unit 101c controls the rotation driving of the rotating drive shafts 105a and 105b such that the rolls 102a and 102b move the substrate sheet 10′ forward in the direction of the arrow shown in FIG. 4 at a speed of, for example, 1 meter a minute.

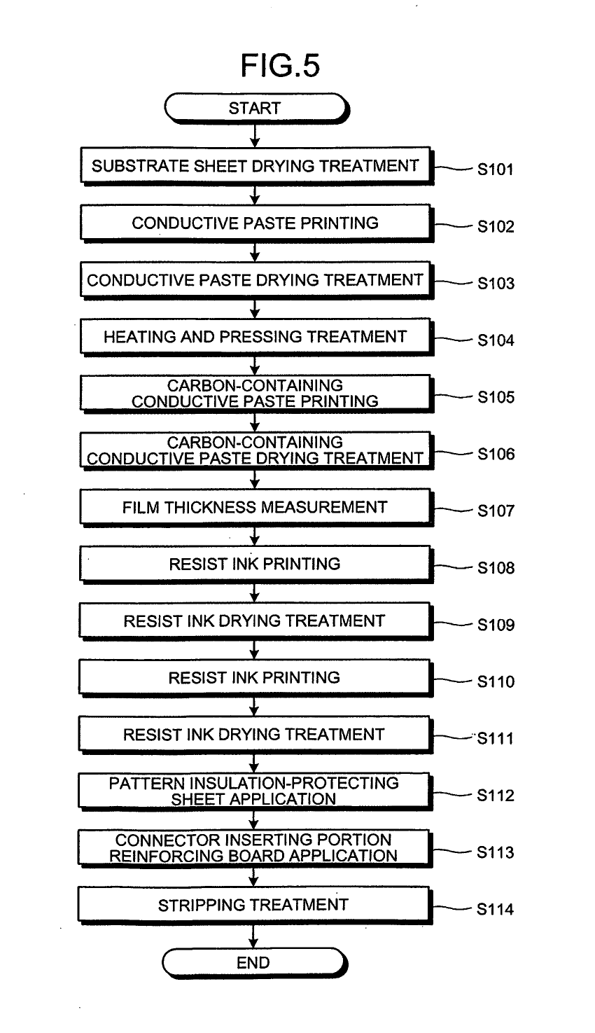

A method of manufacturing a circuit board will be described below. FIG. 5 is a flowchart of manufacturing procedures of a circuit board. As shown in FIG. 5, a drying treatment is performed for a substrate sheet that is a polyester film such that the substrate sheet is left for 2 hours in an atmosphere of 150 degrees centigrade (step S101).

Then, by using a conductive paste into which metal powder and thermoplastic resin are mixed, circuit wiring patterns are printed with a silk screen plate (step S102). Next, a drying treatment is performed for the conductive paste that is used for printing the circuit wiring patterns by leaving the conductive paste for 30 minutes in an atmosphere of 170 degree centigrade (step S103).

Then, a heating and pressing treatment is performed such that the circuit board on which the circuit wiring patterns are printed is heated and pressed, for example, at a heating temperature of 170 degrees centigrade and at a line pressure of 100 kilograms per 50 centimeters (step S104). Next, circuit wiring patterns are printed on a specified connector inserting portion of the circuit board with a silk screen plate by using a carbon-containing conductive paste (step S105).

Then, a drying treatment is performed for the carbon-containing conductive paste that is used for printing the circuit wiring patterns on the specified connector inserting potion by leaving the carbon-containing conductive paste for 30 minutes in an atmosphere of 170 degrees centigrade (step S106).

Next, the thicknesses of the conductive paste and of the film printed by using the carbon-containing conductive paste are measured (step S107), as an inspection process. Then, specified circuit wiring insulation-protecting patterns are printed with a silk screen plate by using resist ink (step S108).

Then, a drying treatment is performed for the resist ink by leaving the resist ink for 30 minutes in an atmosphere of 170 degrees centigrade (step S109). Next, specified circuit wiring insulation-protecting patterns are printed with a silk screen printing plate by using the resist ink (step S110), and a drying treatment is performed for the resist ink by leaving the resist ink for 30 minutes in an atmosphere of 170 degrees centigrade (step S111).

Next, a wiring pattern insulation-protecting sheet is applied to a circuit wiring insulation-protecting portion (step S112), and a reinforcing board is applied on the connector-inserting portion (step S113). Finally, a stripping treatment is performed for the circuit board (step S114).

While a particular embodiment of the present invention has been described, it should be appreciated that the present invention is not limited thereto and that the present invention may be implemented in other various embodiments within the scope and the spirit of the present invention described in the appended claims. In addition, the advantageous effects described in the embodiment are not limited thereto.

Among the various processes described above, all or some of the processes can be performed either automatically or manually. In addition, the process procedures, the control procedures, and the specific names described in the embodiment may be appropriately modified in any manner unless otherwise indicated.

Respective configuration elements of the respective illustrated devices shown in the drawings are functionally conceptual and are not always physically configured as illustrated. Specifically, a specific pattern into which the devices are dispersed or integrated is not limited to the illustrated pattern. The devices may be configured by functionally or physically dispersing or integrating all or some of the devices on any unit in accordance with various loads or usages.

According to one aspect of the present invention, both of the wiring patterns printed by using the first and the second conductive pastes have excellent conductivities, and the second conductive paste can protect the first conductive paste.

According to another aspect of the present invention, the wiring patterns of the circuit board have an excellent conductivity even when silver powder or a mixture of silver powder and cobalt powder is used as metal powder for a conductive paste.

According to still another aspect of the present invention, electric resistance of the whole wiring patterns of the circuit board that are printed by using the first and the second conductive pastes can be suppressed low.

According to still another aspect of the present invention, a circuit board having wiring patterns with an excellent conductivity can be efficiently manufactured.

According to still another aspect of the present invention, manufacturing problems in the pressing treatment can be prevented such as separation of wiring patterns from the circuit board and sticking or seizing up of the wiring patterns to the roll surface. As a result, the production yield of the circuit board can be improved, and the circuit board can be manufactured quickly, efficiently, and at low cost.

According to some aspects of the present invention, a circuit board with an excellent conductivity can be manufactured even when wiring patterns are printed on a substrate by using a conductive paste formed of resin and metal powder that has a high melting point and a high electric resistance.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A circuit board comprising:
a wiring pattern formed by printing on a substrate and including a conductive paste formed of metal powder and thermoplastic resin,
wherein the conductive paste is then subjected to a heating treatment and a pressing treatment.

2. The circuit board according to claim 1,
wherein the metal powder is silver powder or a mixture of silver powder and cobalt powder.

3. The circuit board according to claim 1,
wherein the pressing treatment is performed by using a roll press.

4. The circuit board according to claim 3,
wherein the roll press includes a roll having a mirror finished surface.

5. A circuit board comprising:
a wiring pattern formed by printing on a substrate and including a first conductive paste and a second conductive paste printed on the first conductive paste,
wherein the first conductive paste is metal powder and thermoplastic resin, the second conductive paste is formed of carbon powder and thermoplastic resin, and the first and the second conductive pastes are then subjected to a heating treatment and a pressing treatment.

6. The circuit board according to claim 5,
wherein the metal powder is silver powder or a mixture of silver powder and cobalt powder.

7. The circuit board according to claim 5,
wherein a film thickness of the second conductive paste is smaller than a film thickness of the first conductive paste.

8. The circuit board according to claim 5,
wherein the pressing treatment is performed by using a roll press.

9. The circuit board according to claim 8,
wherein the roll press includes a roll having a mirror finished surface.

10. A method of forming a wiring pattern comprising:
printing a wiring pattern on a substrate with a conductive paste formed of metal powder and thermoplastic resin; and
subjecting the conductive paste to a heating treatment and a pressing treatment.

11. The method according to claim 10,
wherein the metal powder is silver powder or a mixture of silver powder and cobalt powder.

12. The method according to claim 10,
wherein the pressing treatment is performed by using a roll press.

13. The method according to claim 12,
wherein the roll press includes a roll having a mirror finished surface.

14. A method of forming a wiring pattern comprising:
printing a wiring pattern on a substrate with a first conductive paste formed of metal powder and thermoplastic resin;
printing a second conductive paste formed of carbon powder and thermoplastic resin on the first conductive paste; and
subjecting the first and the second conductive pastes to a heating treatment and a pressing treatment.

15. The method according to claim 14,
wherein the metal powder is silver powder or a mixture of silver powder and cobalt powder.

16. The method according to claim 14,
wherein a film thickness of the second conductive paste is smaller than a film thickness of the first conductive paste.

17. The method according to claim 14,
wherein the pressing treatment is performed by using a roll press.

18. The method according to claim 17,
wherein the roll press includes a roll having a mirror finished surface.

19. A method of manufacturing a circuit board comprising:
printing a wiring pattern on a substrate with a conductive paste formed of metal powder and thermoplastic resin; and
subjecting the conductive paste to a heating treatment and a pressing treatment.

20. A method of manufacturing a circuit board comprising:
printing a wiring pattern on a substrate with a first conductive paste formed of metal powder and thermoplastic resin;
printing a second conductive paste formed of carbon powder and thermoplastic resin on the first conductive paste; and
subjecting the first and the second conductive pastes to a heating treatment and a pressing treatment.
